(19) United States
(12) Patent Application Publication
(10) Pub. No.: US 2013/0213473 A1
(43) Pub. Date: Aug. 22, 2013

(54) COMPOSITE SUBSTRATE WITH HIGH THERMAL CONDUCTIVITY

(71) Applicants: YUEH-MU LEE, TAOYUAN COUNTY (TW); ZUN-HAO SHIH, TAOYUAN COUNTY (TW); HWEN-FEN HONG, TAOYUAN COUNTY (TW)

(72) Inventors: YUEH-MU LEE, TAOYUAN COUNTY (TW); ZUN-HAO SHIH, TAOYUAN COUNTY (TW); HWEN-FEN HONG, TAOYUAN COUNTY (TW)

(73) Assignee: ATOMIC ENERGY COUNCIL - INSTITUTE OF NUCLEAR ENERGY RESEARCH, Taoyuan County (TW)

(21) Appl. No.: 13/401,091

(22) Filed: Feb. 21, 2012

(51) Int. Cl. H01L 31/024

(52) U.S. Cl. 136/259

(57) ABSTRACT

The present invention relates to a composite substrate with high thermal conductivity and applicable to concentrating solar power generating plates. The thermal conducting substrate and the circuit substrate are manufactured, respectively, for separating the light concentrating area and the circuit area so that the material with high thermal conductivity can be used completely to the thermal conducting substrate for guiding heat. Then, the material having common thermal conductivity can be chosen as the material for the circuit substrate, which needs no extra thermal conduction. Thereby, regarding to the selection of substrate material, the present can balance well between thermal conducting efficiency and cost control.

### FIELD OF THE INVENTION

The present invention relates generally to a substrate, and particularly to a composite substrate with high thermal conductivity.

### BACKGROUND OF THE INVENTION

With rapid development of industries, fossil fuels are gradually exhausted. In addition, the greenhouse effect and the problem of gas emission attract global concerns daily. The stable supply of energy has become a major subject worldwide. In comparison with traditional coal, natural gas, or nuclear power, solar cells do not consume non-renewable resources. Instead, they convert directly solar energy into electricity by the photoelectric effect. Thereby, no greenhouse effect gases, such as carbon dioxide, nitrogen oxides, and sulfur oxides, and pollutant gases are produced. By reducing dependence on fossil fuels, a safe and autonomous power source is provided.

In a renewable power generating system, solar energy has the advantage of high environmental friendliness and ease of installation. Besides, its technology has become mature for commercialization and national programs are provided for promotion. Nowadays, it has become the major choice of advanced countries for developing distributed power system.

Nevertheless, solar cell technology still needs to be improved in many ways for enhancing its stability and lifetime or reducing its cost. In a concentrating photovoltaic module, while manufacturing the concentrating photovoltaic devices according to prior art, a Fresnel-structure concentrating device is fabricated using plastic materials. The Fresnel concentrating device is arranged corresponding to a surface of solar cells. Then, light can be concentrated on the solar cells according to the characteristics of the Fresnel concentrating device and hence achieving maximum output power.

While performing photovoltaic conversion using concentrating solar cells, owing to the limitations in the absorption spectrum of the material itself, photoenergy cannot be completely converted into electrical energy. Thereby, the excess energy entering the solar cells is either reflected or transmitted. It might also become thermal energy accumulated in the cells and raising temperature of devices. When the temperature is raised, although the probability of carrier generation is increased, the conversion efficiency of the cells is lowered because the dark current is substantially increased inside.

FIG. 1 shows a structural schematic diagram of the solar cell module according the prior art. As shown in the figure, a lens 50 of the concentrating photovoltaic module focuses the sunlight on the surface of the solar cell 40, making the sunlight highly concentrated on the solar cell 40 capable of performing photovoltaic conversion but not the rest area. By concentration, a better power generating efficiency is achieved. Nonetheless, in addition to concentrating light, the focusing inevitably concentrates the heat of the sunlight onto the solar cell 40 as well and hence raising its temperature rapidly. If the excess heat at this area is not dissipated. The power generating efficiency of the solar cell 40 will be reduced. Accordingly, it is imperative to guide the heat away by adopting a substrate with high thermal conductivity.

Moreover, because the temperature rising rate of the area to which the light is concentrated is greater, nonuniformity in temperature occurs on the same substrate and usually resulting in cell explosion and early termination of the life of solar power generating systems.

However, facing such serious heat dissipating problems, if aluminum or copper heat sinks are adopted in solar cell modules for natural heat dissipation, considerable quantities of heat sinks are required, which raise the cost substantially and the cost might be even higher than that of the solar cells themselves. If the forced wind cooling is adopted, a great deal of electrical energy will be used. The power consumed might be greater than that generated. Besides, the lifetime and reliability of fans are low. The maintenance cost of the fans is also a burden.

In a solar cell module, materials with high thermal conductivity are usually considered as the substrate material. If the substrate has high thermal conducting efficiency, the excess heat can exit the solar power generating system rapidly. However, the materials with high thermal conductivity, such as diamond thin films or aluminum nitrides, are quite costly. If such materials are adopted completely, solar cell modules will not be available to all.

Accordingly, under the premise of maintaining power generating efficiency and ensuring lifetime, how to balance between the problems of manufacturing costs and thermal conduction has become a major subject in the solar power generating field.

### SUMMARY

An objective of the present invention is to provide a composite substrate with high thermal conductivity, which has a composite substrate separating the circuit area having lower operating temperature and the solar cell area having extremely high operating temperature and manufactured in different materials. Thereby, the heat in the solar cell area can be guided away via the thermal conducting substrate, which is made of a material having high thermal conductivity, while the circuit substrate of the circuit area can adopt a cheaper material for reducing cost.

Another objective of the present invention is to provide a composite substrate with high thermal conductivity. By means of the thermal conducting substrate with high thermal conductivity, the thermal energy focused on the solar cells can be guided away rapidly, and thus preventing lowering of photovoltaic converting efficiency due to increase in operating temperature.

Still another objective of the present invention is to provide a composite substrate with high thermal conductivity, which can ensure uniform heating of respect substrates and thus avoiding deformation or fracture caused by nonuniform temperatures. Thereby, the lifetime of the solar cell module is guaranteed.

For achieving the objectives described above, the present discloses a composite substrate with high thermal conductivity, which comprises a circuit substrate, a thermal conducting substrate, and an electrical conducting sheet. The circuit substrate has a first electrical conducting area, a second electrical conducting area, and an insulating area. The isolation area separates the first and the second electrical conducting areas; the circuit substrate has an opening portion. The thermal conducting substrate is disposed at the opening portion, and has a third electrical conducting area.

The conducting sheet is connected electrically with the first and the third electrical conducting areas.

### BRIEF DESCRIPTION OF THE DRAWINGS

FIG. 1 shows a structural schematic diagram according the prior art;

FIG. 2 shows a structural schematic diagram according to a preferred embodiment of the present invention;

FIG. 3 shows a partial structural schematic diagram according to a preferred embodiment of the present invention;

FIG. 4 shows a structural schematic diagram of the circuit substrate according to a preferred embodiment of the present invention; and

FIG. 5 shows a structural schematic diagram of the thermal conducting substrate according to a preferred embodiment of the present invention.

### DETAILED DESCRIPTION

In order to make the structure and characteristics as well as the effectiveness of the present invention to be further understood and recognized, the detailed description of the present invention is provided as follows along with embodiments and accompanying figures.

The plurality of solar cell modules according to the prior art adopt a single-substrate structure. For applications in concentrating photovoltaic modules, because high temperature occurs only on a portion of the substrate, the selection of the material of the substrate will be in a dilemma. For solving the drawback, the present invention provides a composite substrate with high thermal conductivity applicable to a concentrating solar power generating system. The design can reduce the required area for the substrate with high thermal conductivity, and hence reducing the cost.

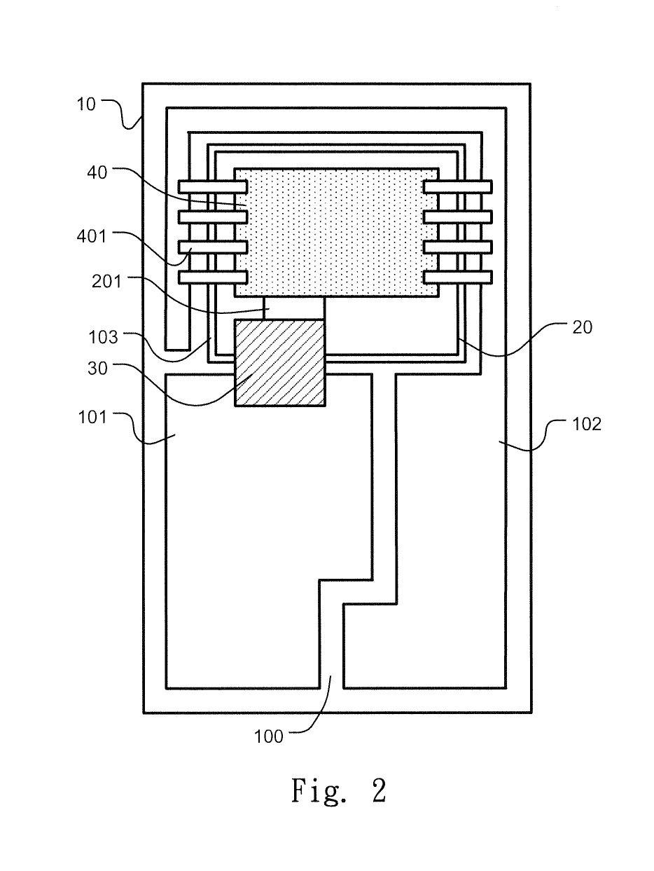

First, please refer to FIG. 2. The composite substrate with high thermal conductivity according to the present invention comprises a circuit substrate 10, an insulating area 100, a first electrical conducting area 101, a second electrical conducting area 102, an opening portion 103, a thermal conducting substrate 20, a third electrical conducting area 201, and a electrical conducting sheet 30.

The first electrical conducting area 101, the second electrical conducting area 102, and the insulating area 100 are all disposed on the circuit substrate 10. The insulating area separates the first and the second electrical conducting areas 101, 102. The circuit substrate 10 has the opening portion 103. The thermal conducting substrate 20 is disposed at the opening portion 103 and has the third electrical conducting area 201. The electrical conducting sheet 30 connects electrically with the first and the third electrical conducting areas 101, 201 so that currents can flow between the circuit substrate 10 and the thermal conducting substrate 20.

In addition to the devices described above, referring again to FIG. 2, the composite substrate with high thermal conductivity according to the present invention further comprises at least a solar cell 40 and a plurality of metal wires 401. The solar cell 40 is disposed above the third electrical conducting area 201, and is connected electrically with the third electrical conducting area 201 via the electrode (not shown in the figure) of the solar cell 40. The plurality of metal wires 401 are connected electrically with the solar cell 40 and the second electrical conducting area 102, so that the latter two form a circuit by means of the metal wires 401.

The key technology of the present invention is characterized in that the circuit substrate 10 and the thermal conducting substrate 20 are composite instead of a single substrate. The circuit substrate 10 and the thermal conducting substrate 20 are connected merely via the electrical conducting sheet 30 with the rest parts untouched. This is different from the single substrate adopted in the prior art.

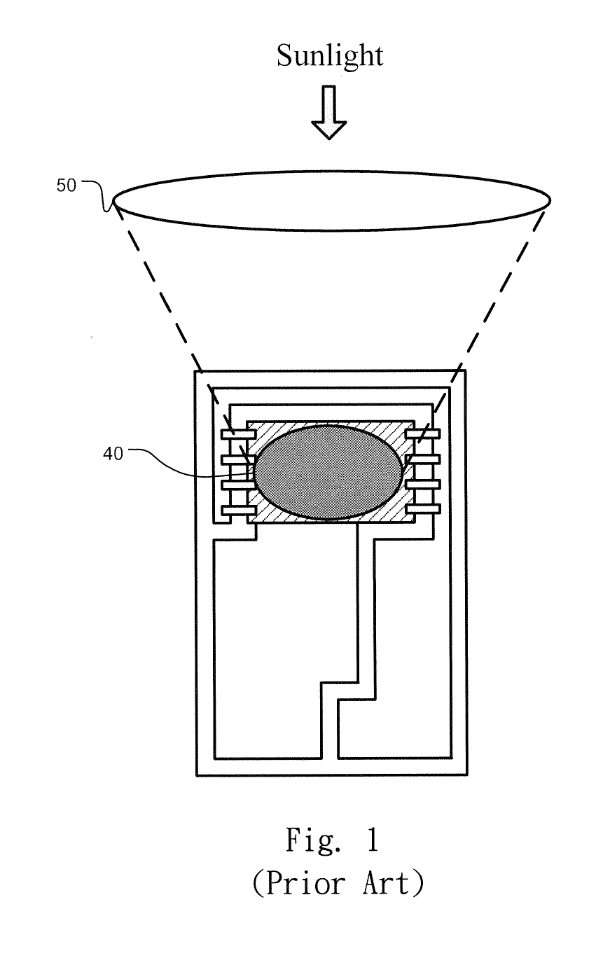

By comparing FIG. 1 with FIG. 2, it should be clearly understood that in order to achieve the best heat dissipating effect at a reasonable cost, the design of the solar cell module according to the present invention adopts the composite substrate. The thermal conducting substrate 20 is the area where the sunlight and heat highly concentrate. Thereby, an insulating material with high thermal conducting efficiency is adopted for manufacturing it. The material thereof can be selected from materials with higher thermal conductivity such as diamond thin films or aluminum nitrides. In particular, the thermal conductivity of diamonds is above 1000 W/mK, making them the primary choice for the material of the thermal conducting substrate 20. In contrast to adopting a costly material having high thermal conducting efficiency as the thermal conducting substrate 20, it is not required to use such a high-thermal-conductivity material for the circuit substrate 10 because the light and heat of the sunlight will not be concentrated in this area. Without the concern of affecting power generating efficiency caused by overheating, a cheap material with common thermal conductivity, such a aluminum oxide, metal-based printed circuit board, or printed circuit board, can be chosen as the substrate material.

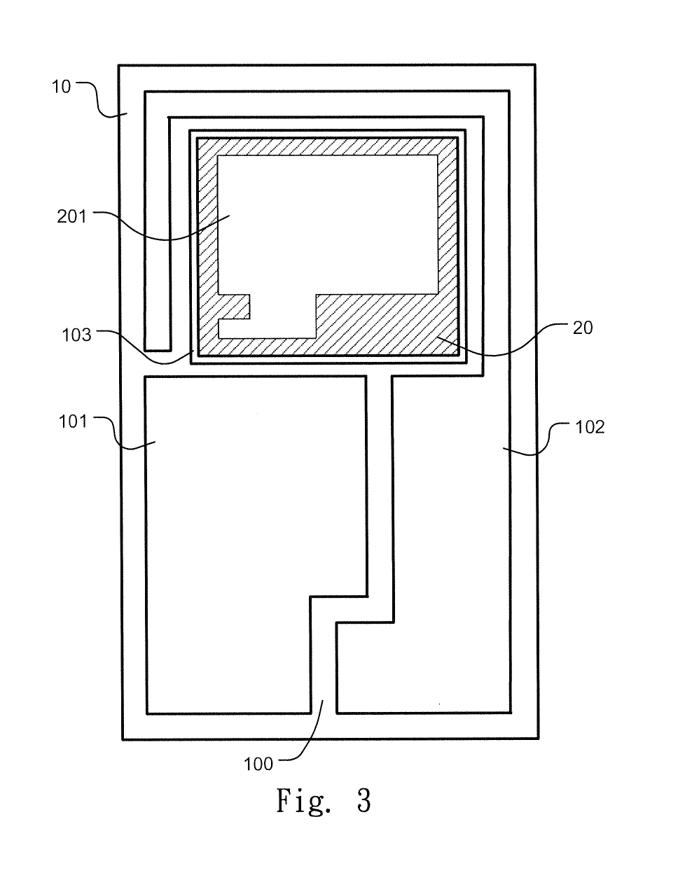

Refer to FIG. 3, in which the electrical conducting sheet 30 according to the present invention removed. According to the relative positions of the circuit substrate 10 and the thermal conducting substrate 20, although the thermal conducting substrate 20 is located at the opening portion 103 of the circuit substrate 10, these two substrates do not contact each other. Thereby, the heat received by the thermal conducting substrate 10 can be guided away through itself smoothly. Even for general usage, though the electrical conducting sheet 30 acting as the circuit channel between the circuit substrate 10 and the thermal conducting substrate 20 has a little thermal conducting capability, most heat generated because of sunlight is still guided away by the thermal conducting substrate 20 and thus maintaining the power generating efficiency of the solar cell 40.

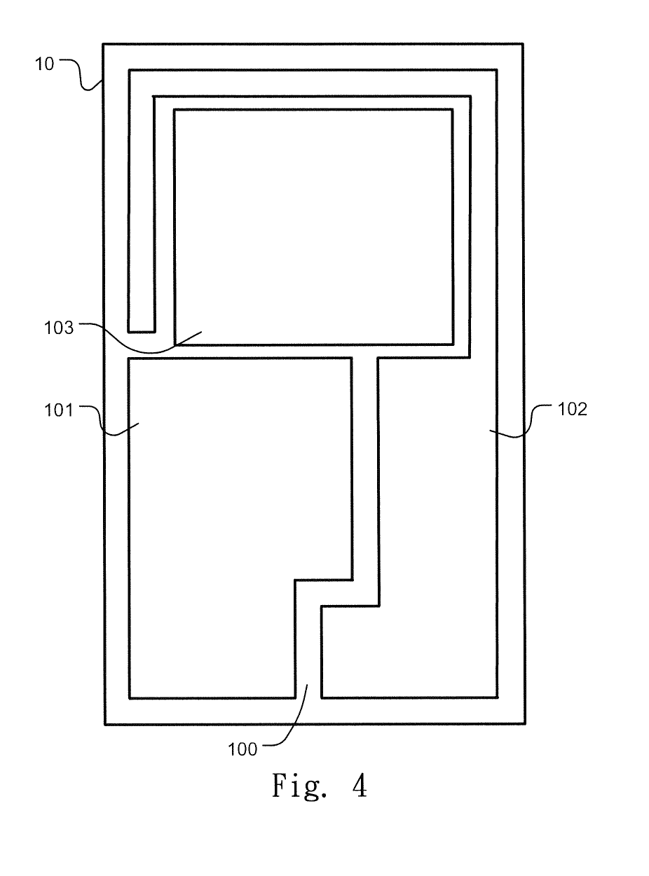

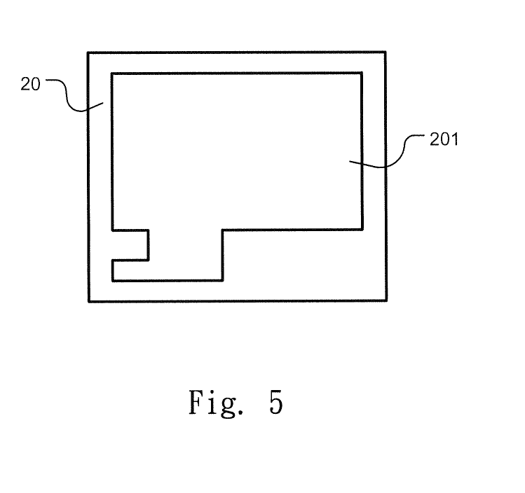

FIG. 4 and FIG. 5 show the structures of the circuit substrate 10 and the thermal conducting substrate 20, respectively. By means of the combination, the thermal conducting substrate 20 with high thermal conductivity can maintain the power generating efficiency of the solar cell 40. Thanks to the independence of the circuit substrate 10 and the thermal conducting substrate 20, which are connected to each other via the electrical conducting sheet 30, the situation of temperature nonuniformity on the same substrate can be prevented, and hence avoiding the possibility of deformation or even fracture. Having the advantage of extending lifetime, the composite substrate with high thermal conductivity according to the present invention can also maintain its cost at a reasonable level as well. It is no longer imperative to adopt costly materials having high thermal conductivity for achieving excellent thermal conducting effect. For reducing cost, it is not necessary to give up heat dissipating effect and adopting cheap materials with common thermal conductivity, either.

Because of the composite substrate with high thermal conductivity, the selection of the substrate material becomes extremely flexible. The correspondingly most-suitable material can be chosen according to the temperature condition encountered in an application, and thereby balancing performance and cost. Consequently, the composite substrate with high thermal conductivity according to the present invention can provide very high commercial value.

Accordingly, the present invention conforms to the legal requirements owing to its novelty, nonobviousness, and utility. However, the foregoing description is only embodiments of the present invention, not used to limit the scope and range of the present invention. Those equivalent changes or modifications made according to the shape, structure, feature, or spirit described in the claims of the present invention are included in the appended claims of the present invention.

1. A composite substrate with high thermal conductivity, comprising:
a circuit substrate, having a first electrical conducting area, a second electrical conducting area, and an insulating area, said insulating area separating said first electrical conducting area and said second electrical conducting area, and said circuit substrate having an opening portion;
a thermal conducting substrate, disposed at said opening portion, and having a third electrical conducting area; and
an electrical conducing sheet, connected electrically with said first electrical conducting area and said third electrical area.

2. A composite substrate with high thermal conductivity of claim 1, and further comprising at least a solar cell disposed above said third electrical conducting area.

3. A composite substrate with high thermal conductivity of claim 2, and further comprising a plurality of metal wires connected electrically with said solar cell and said second electrical conducting area.

4. A composite substrate with high thermal conductivity of claim 1, wherein the material of said thermal conducting substrate is selected from the group consisting of diamond thin film and aluminum nitride.

5. A composite substrate with high thermal conductivity of claim 1, wherein the material of said circuit substrate is selected from the group consisting of aluminum oxide, metal-based printed circuit board, and printed circuit board.
